(19) United States
(12) Patent Application Publication
(10) Pub. No.: US 2008/0003780 A1
(43) Pub. Date: Jan. 3, 2008

(54) Detachable stiffener for ultra-thin die

(76) Inventors: Haixiao Sun, Pudong (CN); Daoqiang Lu, Chandler, AZ (US)

Correspondence Address: INTEL/BLAKELY, 1279 OAKMEAD PARKWAY, SUNNYVALE, CA, 94085-4040, US

(21) Appl. No.: 11/479,834

(22) Filed: Jun. 30, 2006

(51) Int. Cl. H01L 21/30

(52) U.S. Cl. 438/464; 257/E23.002

(57) ABSTRACT

A technique to fabricate a package. A thin wafer supported by a wafer support substrate (WSS) is formed. The WSS-supported thin wafer is mounted onto a stiffener. The WSS is released from the thin wafer. The thin wafer and the stiffener are diced into a plurality of stiffener-reinforced dice.

### BACKGROUND

1. Field of the Invention

Embodiments of the invention relate to the field of semiconductor, and more specifically, to semiconductor packaging.

2. Description of Related Art

The demand for small footprint devices for use in applications such as smart cards, cellular devices, mobile communication, and mobile computing has led to many challenges in fabrication technologies. One such challenge is the development of ultra-thin packages.

Ultra-thin packages require reduced die thickness. The reduction of the die thickness becomes even more difficult as the diameter of the wafer is increased. There are currently four primary methods for wafer thinning: mechanical grinding, chemical mechanical polishing (CMP), wet etching, and atmospheric downstream plasma (ADP) dry chemical etching (DCE). During the fabrication phase, handling ultra-thin devices is difficult. Existing techniques to facilitate handling of ultra-thin dice or wafers have a number of disadvantages. For example, use of adhesive tapes is limited by the non-uniformity of the tape. Most of the available glues are thermally stable up to about 120° C., which may be too low for additional thermal processing. Other techniques such as dicing before grinding (DBG) or dicing by thinning (DbyT) may cause additional damage to the dice or wafers.

### BRIEF DESCRIPTION OF THE DRAWINGS

Embodiments of invention may best be understood by referring to the following description and accompanying drawings that are used to illustrate embodiments of the invention. In the drawings:

FIG. 1A is a diagram illustrating a manufacturing system in which one embodiment of the invention can be practiced.

FIG. 1B is a diagram illustrating a system according to one embodiment of the invention.

FIG. 2A is a diagram illustrating a wafer assembly with a wafer support substrate according to one embodiment of the invention.

FIG. 2B is a diagram illustrating a wafer assembly with thinned wafer according to one embodiment of the invention.

FIG. 2C is a diagram illustrating a wafer assembly with a stiffener according to one embodiment of the invention.

FIG. 2D is a diagram illustrating a wafer assembly without the WSS according to one embodiment of the invention.

FIG. 2E is a diagram illustrating a diced wafer assembly according to one embodiment of the invention.

FIG. 3 is a diagram illustrating placing die assembly to a substrate according to one embodiment of the invention.

FIG. 4 is a flowchart illustrating a process to package a stiffener-reinforced device dice according to one embodiment of the invention.

FIG. 5 is a flowchart illustrating a process to form a thin wafer supported by WSS according to one embodiment of the invention.

FIG. 6 is a flowchart illustrating a process to assemble a stiffener-reinforced die into a package according to one embodiment of the invention.

### DESCRIPTION

An embodiment of the present invention is a technique to fabricate a package. A thin wafer supported by a wafer support substrate (WSS) is formed. The WSS-supported thin wafer is mounted onto a stiffener. The WSS is released from the thin wafer. The thin wafer and the stiffener is diced into a plurality of stiffener-reinforced dice

In the following description, numerous specific details are set forth. However, it is understood that embodiments of the invention may be practiced without these specific details. In other instances, well-known circuits, structures, and techniques have not been shown to avoid obscuring the understanding of this description.

One embodiment of the invention may be described as a process which is usually depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. A process may correspond to a method, a program, a procedure, a method of manufacturing or fabrication, etc.

An embodiment of the present invention is a technique to provide mechanical support for ultra-thin wafers or dice to facilitate their handling and processing. After mounted onto a wafer support substrate (WSS), the wafer is thinned to a desired thickness and then a backside metallurgy is deposited on the backside of the wafer. Then, the WSS-supported wafer assembly is mounted onto a low-cost stiffener wafer through a thin layer of sacrificial polymer. The WSS is then released from the wafer front side. The wafer assembly and the stiffener are mounted on a dicing tape and diced together into individual dice. The individual die with stiffener is then attached to a substrate for packaging. A reflow process is performed to form Controlled Collapse Chip Connection (C4) solder joints. During reflow, the sacrificial polymer between the die and the stiffener is decomposed into gases and the stiffener may be detached or removed easily. In another embodiment, the stiffener may be replaced by a thicker layer of sacrificial polymer without using the stiffener wafer. The advantage of this embodiment is that the removal of stiffener after reflow is not necessary. In another embodiment, the WSS-supported wafer assembly is attached to a stiffener wafer through a layer of water soluble polymer adhesive. This adhesive may dissolve in water and thus the stiffener may be detached during the defluxing phase after WSS supported die is attached on a substrate. The technique thus provides superior mechanical support and/or reinforcement to facilitate handling the dice during the packaging process.

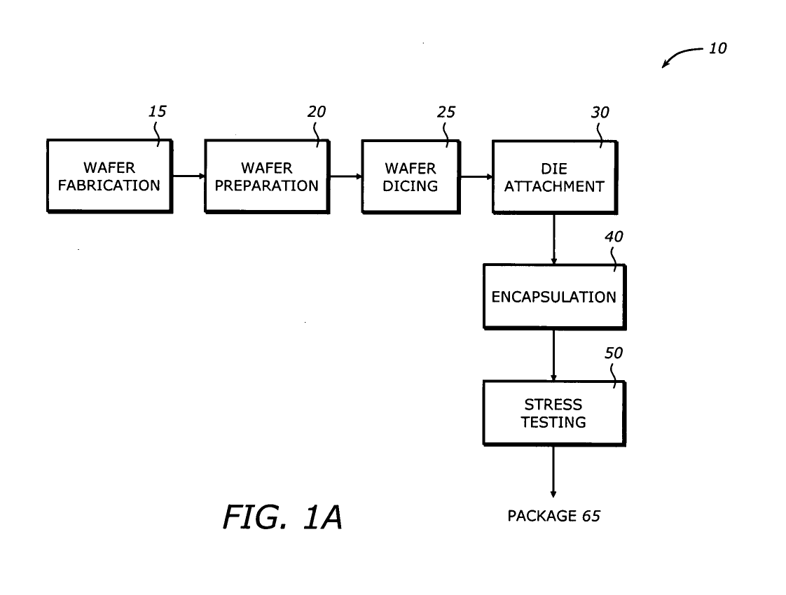

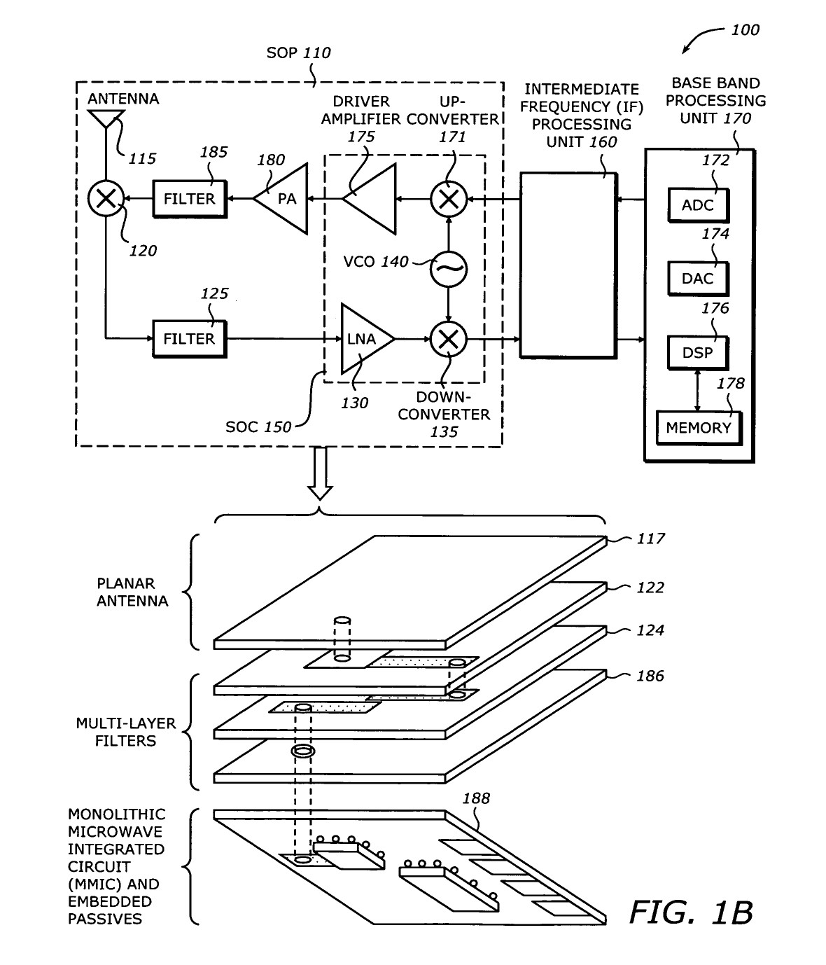

FIG. 1A is a diagram illustrating a manufacturing system 10 in which one embodiment of the invention can be practiced. The system 10 includes a wafer fabrication phase 15, wafer preparation phase 20, a wafer dicing phase 25, a die attachment phase 30, an encapsulation phase 40, and a stress testing phase 50. The system 10 represents a manufacturing flow of a semiconductor packaging process.

The wafer fabrication phase 15 fabricates the wafer containing a number of dice. The individual dice may be any microelectronic devices such as microprocessors, memory devices, interface circuits, etc. The wafer fabrication phase 15 includes typical processes for semiconductor fabrication such as preparation of the wafer surface, growth of silicon dioxide (SiO₂), patterning and subsequent implantation or diffusion of dopants to obtain the desired electrical properties, growth or deposition of a gate dielectric, and growth or deposition of insulating materials, depositing layers of metal and insulating material and etching it into the desired patterns. Typically the metal layers consist of aluminium or copper. The various metal layers are interconnected by etching holes, called “vias,” in the insulating material.

The wafer preparation phase 20 prepares a wafer containing dice for packaging and testing. During this phase, the wafers are sorted after the patterning process. An inspection may be carried out to check for wafer defects. Then, the wafer may be mounted on the WSS that adheres to the front side or bump side of the wafer, and the wafer is thinned to a desired thickness. The WSS provides mechanical support for handling during subsequent phases. The wafer may be further mounted onto the stiffener wafer.

The wafer dicing phase 25 dices, cuts, or saws the wafer with stiffener into individual dice. High precision saw blade and image recognition unit may be used. De-ionized water may be dispensed on the wafer to wash away any residual particles or contaminants during the dicing. Then, the wafer is dried by being spun at high spinning speed.

The die attachment phase 30 attaches the stiffener supported die to a package substrate. The substrate material depends on the packaging type. It may be made of an organic or inorganic material. The stiffener may be removed easily during the die attachment step.

The encapsulation phase 40 underfills the die and the substrate. Underfill material may be dispensed between the die and the substrate. Integrated heat spreader (IHS) may be attached to the die and substrate assembly. The fully assembled package 65 may be ready to be tested.

The stress testing phase 50 performs one or more tests such as Highly Accelerated Stress Test (HAST) or biased-HAST on the device package under stress conditions. A test chamber may be designed to conduct a stress test. It may have monitoring circuits, measurement circuits, and other data processing equipment. The package 65 is placed in the test chamber subject to the stress test. It may be powered or non-powered. Various stress tests may be performed on the wafer or on the packaged devices 65 at various points of the manufacturing process flow. The tests may follow standards such as Joint Electron Device Engineering Council (JEDEC) standards or military standards. Examples of these tests may include electrostatic discharge (ESD), or human body model (HBM), high temperature operational life (HTOL), thermal shock, temperature cycle, high temperature storage, vibration and mechanical loading, shear testing, and accelerated moisture resistance.

FIG. 1B is a diagram illustrating a system 100 according to one embodiment of the invention. The system 100 represents a mobile communication module. It includes a system on package (SOP) 110, an intermediate frequency processing unit 160, and a base-band processing unit 170.

The SOP 110 represents the front end processing unit for the mobile communication module. It is a transceiver incorporating on-package integrated lumped passive components as well as radio frequency (RF) components. It includes an antenna 115, a duplexer 120, a filter 125, a system-on-chip (SOC) 150, a power amplifier (PA) 180, and a filter 185.

The antenna 115 receives and transmits RF signals. The RF signals may be converted to digital data for processing in subsequent stages. It is designed in compact micro-strip and strip-line for L and C-band wireless applications. The duplexer 120 acts as a switch to couple to the antenna 115 to the receiver and the transmitter to the antenna 115. The filters 125 and 185 are C-band LTCC-strip-line filter or multilayer organic lumped-element filter at 5.2 GHz and narrowband performance of 200 MHz suitable for the Institute of Electrical and Electronic Engineers (IEEE) 802.11 wireless local area network (WLAN). The SOC 150 includes a low noise amplifier (LNA) 130, a down converter 135, a local voltage controlled oscillator (VCO) 140, an up converter 171, and a driver amplifier 175. The LNA 130 amplifies the received signal. The down converter 135 is a mixer to convert the RF signal to the IF band to be processed by the IF processing unit 160. The up converter 171 is a mixer to convert the IF signal to the proper RF signal for transmission. The VCO 140 generates modulation signal at appropriate frequencies for down conversion and up conversion. The driver amplifier 175 drives the PA 180. The PA 180 amplifies the transmit signal for transmission.

The IF processing unit 160 includes analog components to process IF signals for receiving and transmission. It may include a band-pass filter and a low pass filter at suitable frequency bands. The filter may provide base-band signal to the base-band processing unit 170. The base-band processing unit 170 may include an analog-to-digital converter (ADC) 172, a digital-to-analog converter (DAC) 174, a digital signal processor (DSP) 176, and memory device 178. The ADC 172 and the DAC 174 are used to convert analog signals to digital data and digital data to analog signal, respectively. The DSP 176 is a programmable processor that may execute a program to process the digital data. The memory device 178 may be flash memories or random access memories. It may be packaged using Flip-Chip Ball Grid Array (FCBGA) packaging technology, a molded packaging, or any other suitable packaging technologies. The memory device 178 may be manufactured according to the manufacturing flow 10 shown in FIG. 1A. It may be the device package 65. The base-band processing unit 170 may also include memory and peripheral components. The DSP 176 may, therefore, be coupled to the front end processing unit via the IF processing unit 160 and/or the base-band processing unit 170 to process the digital data.

The SOP 110 may be a multi-layer three-dimensional (3D) architecture for a monolithic microwave integrated circuit (MMIC) with embedded passives (EP) technology. It may be implemented using Low Temperature Co-fired Ceramics (LTCC) and organic-based technologies. The 3D architecture may include multiple layers include a layer 117 to implement the antenna 115, layers 122, 124, and 186 for the filters 125 and 185, and layer 188 for the SOC 150 and the passive components using EP technology. Typically, the packaging technology involves embedded passives with multiple layers.

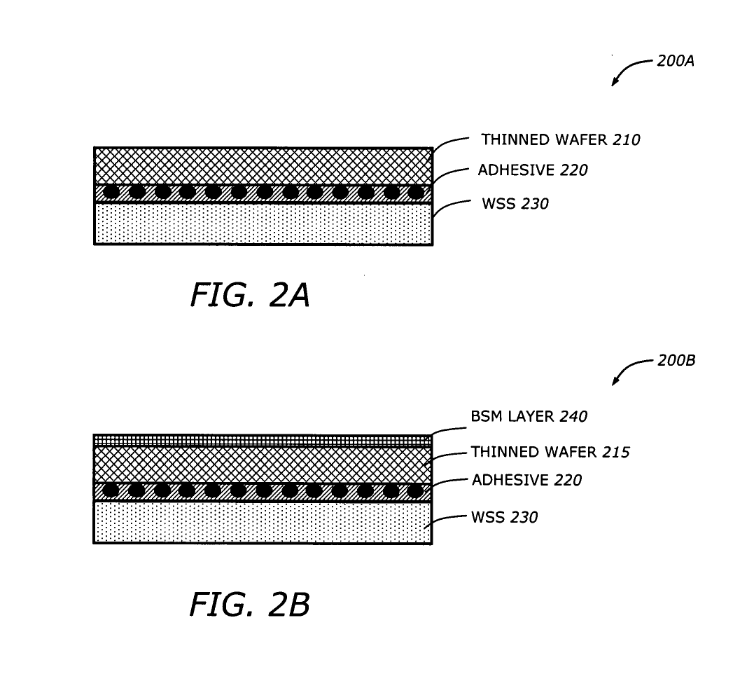

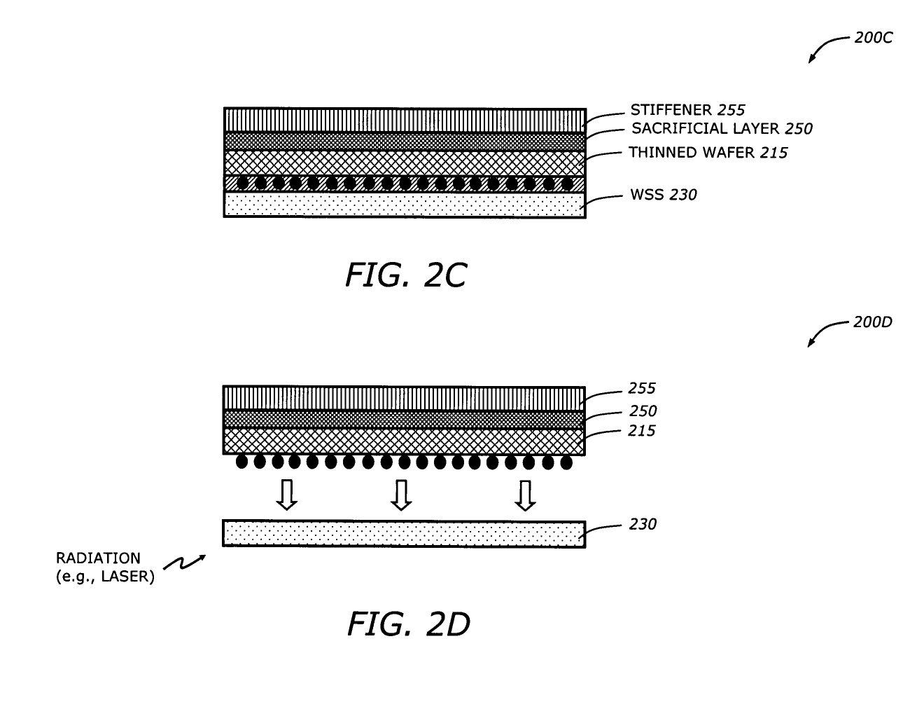

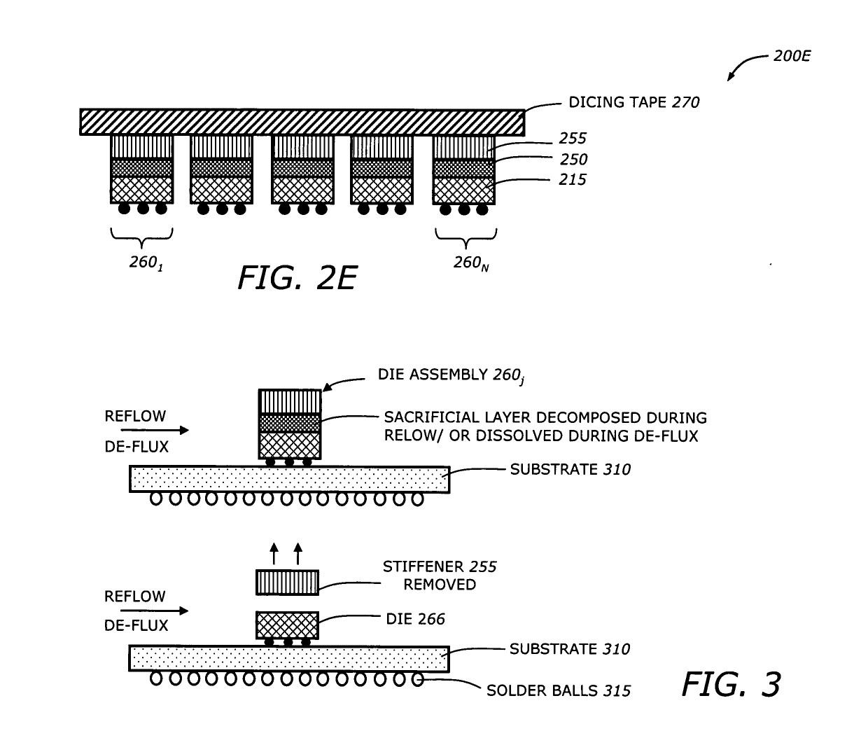

FIG. 2A is a diagram illustrating a wafer assembly 200A with a wafer support substrate according to one embodiment of the invention. The wafer assembly 200A includes a bumped wafer 210, an adhesive 220, and a WSS 230.

The bumped wafer 210 is any wafer that has been processed and having the bumps attached to the front side. The adhesive 220 may be any suitable polymer adhesive to attach the WSS 230 to the bumped wafer 210.

The WSS 230 may be any suitable support substrate, such as a glass wafer, a blank silicon wafer, or a glass support plate. The bumped wafer 210 is mounted onto the WSS 230 using the adhesive 220 as an attachment material.

FIG. 2B is a diagram illustrating a wafer assembly 200B with thinned wafer according to one embodiment of the invention. The wafer assembly 200B includes a thinned wafer 215, the adhesive 220, the WSS 230 and a backside metallurgy (BSM) layer 240. The wafer assembly 200B is formed from the wafer assembly 200A by thinning the bumped wafer 210 and depositing the BSM layer 240.

The thinned wafer 210 may be thinned from the bumped wafer 210 using any suitable thinning technique such as grinding, chemical mechanical polishing, etc. The thinned wafer 210 may have a thickness of less than 75 μm. After thinning, the BSM layer 240 is deposited on the backside of the thinned wafer 215. The BSM layer 240 may include several metal layers such as titanium (Ti), nickel (Ni) and gold (Au). It may also include a solder or solder alloy material such as In—Ag, Sn—Cu, or Sn—Ag—Cu, which may form high temperature solder joint at a low bonding temperature.

FIG. 2C is a diagram illustrating a wafer assembly 200C with a stiffener according to one embodiment of the invention. The wafer assembly 200C includes the thinned wafer 215, the WSS 230, a sacrificial layer 250, and a stiffener 255. The wafer assembly 200C is formed from the wafer assembly 200B by depositing the sacrificial layer 250 and mounting the WSS-supported thin wafer onto the stiffener 255.

In one embodiment, the sacrificial layer 250 may be any suitable polymer adhesive that may be decomposed at high temperature. Examples of the adhesive may include certain polynorbornenes (e.g., Unity series from Premerus) and poly (alkyl carbonates) (e.g., QPAC series from Empower Materials). In another embodiment, the sacrificial layer 250 may be a layer of water soluble polymer adhesive that may dissolve by water during de-fluxing. The sacrificial layer 250 may be applied to the bumped wafer 210 using any suitable technique such as spin-coating, spray-coating, or lamination. Additional processing on the wafer after application of the sacrificial layer 250 may be used, such as soft baking or lithographic exposure.

The stiffener 255 may be any suitable low cost wafer such as polysilicon wafer. It is used mainly as a temporary mechanical reinforcement to facilitate the handling of the ultra-thin wafer 215 or the resulting singulated dice. In one embodiment, the stiffener 255 may be replaced by a sacrificial layer such as the sacrificial layer 250. The sacrificial layer 250 may have an appropriate thickness to provide mechanical reinforcement for the thinned wafer and the singulated dice.

FIG. 2D is a diagram illustrating a wafer assembly 200D without the WSS according to one embodiment of the invention. The wafer assembly 200D is formed from the wafer assembly 200C by releasing the WSS 230. The wafer assembly 200D therefore includes the thinned wafer 215, the sacrificial layer 250, and the stiffener 255. In embodiments where the stiffener 255 is not needed, the wafer assembly 200D includes only the thinned wafer 215 and the sacrificial layer 250 with appropriate thickness.

The WSS 230 is released from the wafer assembly 200D using a radiation beam such as laser or ultraviolet (UV), to decompose the polymer of the sacrificial adhesive. In one embodiment, an excimer laser may be used as the radiation source. The wavelengths may include 157 nm, 193 nm, 248 nm, 308 nm, or 351 nm. Alternatively, a Yttrium Aluminum Garnett (YAG) laser may be used with a wavelength (e.g., 262 nm, 263 nm, 266 nm, 349 nm, 351 nm, or 355 nm). A laser capable of delivering between about 0.01 Watt to 1 Watt may be used.

FIG. 2E is a diagram illustrating a diced wafer assembly 200E according to one embodiment of the invention. The diced wafer assembly 200E includes N diced or singulated die assemblies 260₁ to 260_{N}, and a dicing tape 270. The diced wafer assembly 200E is formed from the wafer assembly 200D by mounting the wafer assembly 200D onto the dicing tape 270 and dicing the thinned wafer 215 together with the stiffener 255 into the die assemblies 260₁ to 260_{N}.

The dicing tape 270 holds the stiffener-supported thin wafer 200D before and after dicing. It may be any flexible Polyvinyl Chloride (PVC) with synthetic acrylic bonded to one side. It holds the singulated dice 260₁ to 260_{N} after dicing. The stiffener-supported thin wafer 200D, including the stiffener 255, the sacrificial layer 250, and the thinned wafer 215, may be diced using any suitable dicing technology such as diamond blades.

Each of the singulated dice 260₁ to 260_{N} includes a stiffener 262 cut from the stiffener 255, a sacrificial layer 264 cut from the sacrificial layer 250, and a die 266 from the thinned wafer 215. The die 266 has the bumps 268. The stiffener 262 provides a temporary mechanical reinforcement of the die to facilitate subsequent handling operations. As discussed above, in one embodiment, the stiffener 262 may not be needed and the sacrificial layer 264 with appropriate thickness may be used as a stiffener instead.

FIG. 3 is a diagram illustrating placing die assembly to a substrate according to one embodiment of the invention. The die assembly 260ⱼ (j=1, . . . , N) is placed on a substrate 310 by a pick-and-place mechanism. The die assembly 260ⱼ is then attached to the substrate 310 by a reflow process.

The substrate 310 is a package substrate that provides support for the die assembly 280. The substrate 310 may be polymer or a composite. The substrate 310 may be selected for any suitable packaging technologies including Ball Grid Array (BGA), Pin Grid Array (PGA), or Land Grid Array (LGA). A number of solder balls 315 may be attached to the substrate 310. The solder balls 315 allow attachment of the die assembly 260ⱼ to a circuit board or to any other mounting component. The die assembly 260ⱼ includes the die 266. The die 266 may be a microelectronic device such as a microprocessor, a memory, an interface chip, an integrated circuit, etc. The die assembly 260ⱼ is attached to the substrate 310 by a number of solder bumps 268. The bumps 268 provide contact with the contact pads on the substrate. The bumps 268 may be fabricated using any standard manufacturing or fabrication techniques such as the controlled collapse chip connect (C4) technique.

The reflow applies heat to the bumps 268 to attach the die assembly 260ⱼ to the substrate 310. The reflow temperature may be at a temperature to decompose the sacrificial layer 264. In one embodiment, this temperature may be in the range of approximately 180° C. to 200° C. The sacrificial layer 264 may be decomposed into gases. The decomposition causes the detachment of the stiffener 262 and it may be detached or removed from the die assembly 260ⱼ easily, leaving only the die 266 attached to the substrate 310. In the embodiment where the stiffener 262 is replaced by the sacrificial layer 264 with appropriate thickness, the sacrificial layer 264 may decompose completely. Accordingly, in this embodiment, there is no need to remove the stiffener. In the embodiment where the sacrificial layer 264 is a water soluble polymer, the water soluble polymer may dissolve into water and thus the stiffener may be detached during the defluxing step.

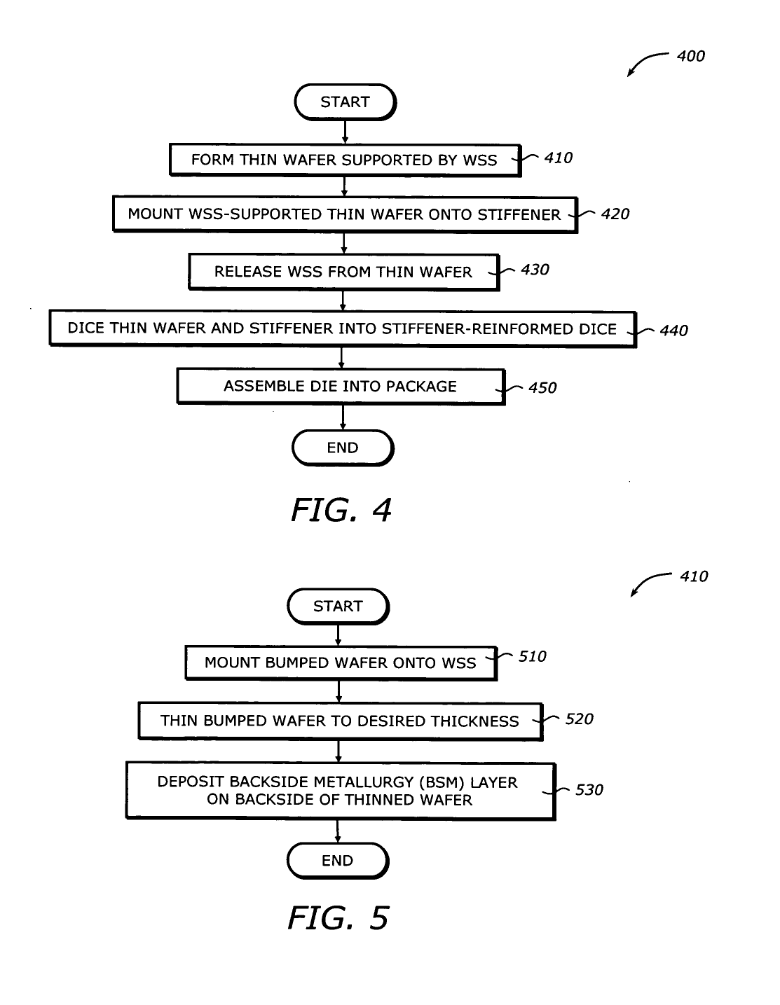

FIG. 4 is a flowchart illustrating a process 400 to package a stiffener-reinforced device dice according to one embodiment of the invention.

Upon START, the process 400 forms a thin wafer supported by a WSS (Block 410). Next, the process 400 mounts the WSS-supported thin wafer onto a stiffener (Block 420). The stiffener may be a polysilicon wafer attached to a sacrificial layer or only a thick sacrificial layer with appropriate thickness. Then, the process 400 releases the WSS from the thin wafer (Block 430). The release of the WSS may be accomplished using a laser or UV beam to weaken or decompose the local adhesive that attaches the WSS to the wafer. Next, the process 400 dices the thin wafer and the stiffener into a plurality of stiffener-reinforced dice (Block 440). Then, the process 400 assembles the stiffener-reinforced die into a package (Block 450). The process 400 is then terminated.

FIG. 5 is a flowchart illustrating the process 410 shown in FIG. 4 to form a thin wafer supported by WSS according to one embodiment of the invention.

Upon START, the process 410 mounts a bumped wafer onto the WSS (Block 510). The attachment to the WSS may use an appropriate adhesive that may be weakened later by a laser beam or UV light when the WSS is released from the wafer. Next, the process 410 thins the bumped wafer to a desired thickness (Block 520). For ultra-thin wafer, the desired thickness may be less than 75 μm. Then, the process 410 deposits a backside metallurgy (BSM) layer on backside of the thinned wafer (Block 530) and is then terminated.

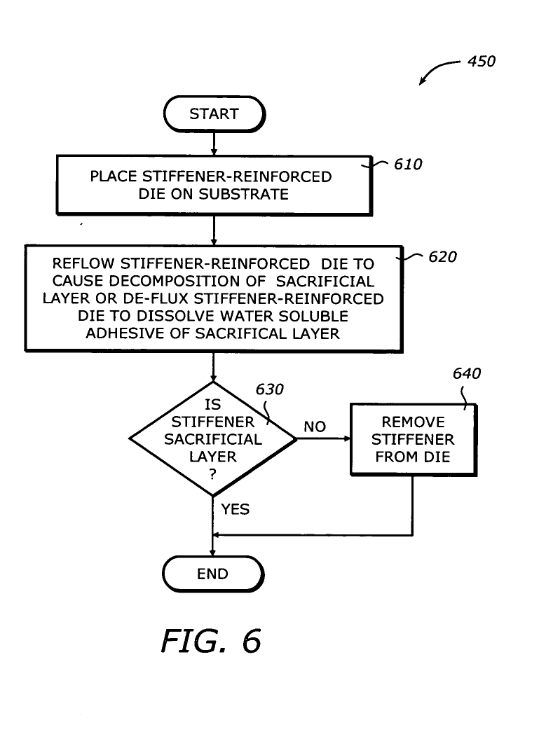

FIG. 6 is a flowchart illustrating the process 450 shown in FIG. 4 to assemble the stiffener-reinforced die into a package according to one embodiment of the invention.

Upon START, the process 450 places a stiffener-reinforced die on a substrate (Block 610). Then, the process 450 reflows the stiffener-reinforced die to attach the bumps on the die to the substrate or de-flux the stiffener-reinforced die (Block 620). The reflow generates heat and causes decomposition of the sacrificial layer or the de-flux operation dissolves the sacrificial layer that is made of water soluble polymer adhesive. The process 450 determines if the stiffener is the sacrificial layer (Block 630). If it is, then process 450 is terminated because the sacrificial layer decomposes into gases completely or dissolve by water during a defluxing operation. Otherwise, the process 450 removes the stiffener from the die (Block 640) and is then terminated.

While the invention has been described in terms of several embodiments, those of ordinary skill in the art will recognize that the invention is not limited to the embodiments described, but can be practiced with modification and alteration within the spirit and scope of the appended claims. The description is thus to be regarded as illustrative instead of limiting.

What is claimed is:

1. A method comprising:
forming a thin wafer supported by a wafer support substrate (WSS);
mounting the WSS-supported thin wafer onto a stiffener;
releasing the WSS from the thin wafer; and
dicing the thin wafer and the stiffener into a plurality of stiffener-reinforced dice.

2. The method of claim 1 wherein forming the thin wafer comprises:
mounting a bumped wafer onto the WSS;
thinning the bumped wafer to a desired thickness; and
depositing a backside metallurgy (BSM) layer on backside of the thinned wafer.

3. The method of claim 2 wherein mounting the WSS-supported thin wafer comprises:
mounting the WSS-supported thin wafer onto the stiffener through a sacrificial layer or a layer of water soluble polymer adhesive, the stiffener being a substrate wafer.

4. The method of claim 2 wherein mounting the WSS-supported thin wafer comprises:
mounting the WSS-supported thin wafer onto the stiffener being a sacrificial layer.

5. The method of claim 3 further comprises:
placing a stiffener-reinforced die on a substrate; and
reflowing the stiffener-reinforced die to cause decomposition of the sacrificial layer; and
removing the stiffener from the die.

6. The method of claim 3 further comprises:
placing a stiffener-reinforced die on a substrate;
de-fluxing the stiffener-reinforced die to dissolve the water soluble polymer adhesive; and
removing the stiffener from the die.

7. The method of claim 4 further comprises:
placing a stiffener-reinforced die on a substrate; and
reflowing the stiffener-reinforced die to cause decomposition of the sacrificial layer.

8. The method of claim 2 wherein thinning the bumped wafer comprises:
thinning the bumped wafer to the desired thickness of less than 75 μm.

9. The method of claim 2 wherein releasing the WSS comprises:
directing a laser or ultraviolet (UV) beam to decompose adhesive attaching the WSS and the thin wafer.

10. A die assembly comprising:
a substrate;
a die thinned to a desired thickness attached to the substrate via bumps; and
a sacrificial layer attached to backside of the die.

11. The die assembly of claim 10 further comprising:
a stiffener attached to the sacrificial layer to provide mechanical reinforcement for the die.

12. The die assembly of claim 10 wherein the sacrificial layer is made of polynorbornenes or poly (alkyl carbonates).

13. The die assembly of claim 10 wherein the sacrificial layer is made of a water soluble polymer adhesive.

14. The die assembly of claim 11 wherein the stiffener is made of polysilicon.

15. The die assembly of claim 10 wherein the desired thickness is less than 75 μm.

16. The die assembly of claim 10 wherein the sacrificial layer is decomposed into gases when the bumps are reflowed.

17. The die assembly of claim 13 wherein the sacrificial layer is dissolved into water during a de-flux operation.

18. A wafer assembly comprising:
a bumped wafer thinned to a desired thickness;
a sacrificial layer attached to backside of the bumped wafer; and
a wafer support substrate (WSS) attached to front side of the bumped wafer.

19. The wafer assembly of claim 18 further comprising:
a stiffener wafer attached to the sacrificial layer to provide mechanical reinforcement for the bumped wafer.

20. The wafer assembly of claim 18 wherein the sacrificial layer is made of polynorbornenes or poly (alkyl carbonates).

21. The wafer assembly of claim 18 where in the sacrificial layer is made of a water soluble polymer adhesive.

22. The wafer assembly of claim 19 wherein the stiffener wafer is a polysilicon wafer.

23. The wafer assembly of claim 18 wherein the desired thickness is less than 75 μm.
